(19) United States
(12) Patent Application Publication
(10) Pub. No.: US 2007/0298532 A1
(43) Pub. Date: Dec. 27, 2007

(54) Micro-Electro-mechanical (MEMS) encapsulation using buried porous silicon

(76) Inventor: Andrew Machauf, Mevasseret Zyon (IL)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/476,392

(22) Filed: Jun. 27, 2006

(51) Int. Cl. H01L 21/00

(52) U.S. Cl. 438/48

(57) ABSTRACT

An apparatus comprising a substrate having therein one or more porous regions, a micro-electro-mechanical (MEMS) device formed on the substrate, a cap formed on the substrate, wherein the cap encapsulates the MEMS device and is formed over at least one of the one or more porous regions, and a sealing layer formed on a back side of the substrate. A process comprising forming one or more porous regions in a substrate, forming a micro-electro-mechanical (MEMS) device on the substrate, forming a sacrificial layer on the substrate over the MEMS device, wherein the sacrificial layer is over at least one of the one or more porous regions, forming a cap on the substrate, wherein the cap encapsulates the MEMS device and the sacrificial layer, etching the sacrificial layer inside the cap by inserting etchant through at least one of the one or more porous regions, and forming a sealing layer on a back side of the substrate.

### TECHNICAL FIELD

The present invention relates generally to micro-electro-mechanical (MEMS) devices and systems and in particular, but not exclusively, to encapsulation of MEMS devices using buried porous silicon.

### BACKGROUND

Micro-electro-mechanical devices, commonly known as MEMS devices, are very small-scale devices that can include movable mechanical components as well as electronic components. Because of the very small scale of the components in a MEMS device, MEMS devices can be very sensitive to environmental conditions. MEMS devices operate through mechanical movement of a moving member, so the gaps between MEMS components that move relative to each other must be clear of any particulate matter that may inhibit movement. Electrical components of a MEMS device must also, for example, be free of stiction-causing films that can develop when the device is exposed to certain environments. Stiction is an adhesive or electrostatic attraction between electrodes that can have a negative impact on the switching speed and response of a device such as a MEMS switch. When the voltage potential is removed, the electrodes should separate instantaneously; any residual, unwanted attraction between electrodes will increase the time for separation, thereby decreasing switching speed. In extreme cases, stiction may bind a MEMS switch in the closed position, thus rendering it inoperable.

One way to avoid environmental effects is to incorporate a MEMS device with other components as part of a system and to enclose the entire system in a hermetically sealed package, but past implementations of this approach have increased the size and cost of the system and have tended to limit the position of the MEMS device to an exposed surface of the system. The increase in size also necessitates long vias to connect the MEMS device with radiators and other components leading to losses and increased noise, particularly at high frequencies.

Another way to avoid adverse environmental effects is to individually enclose one or more MEMS devices in a hermetically sealed package prior to incorporating the devices into a system with other components. Ceramic packages with metal seals have been proposed for this purpose, but the mating process requires significant handling of the MEMS devices in an unprotected condition. If a number of MEMS devices are formed in a batch on a single wafer the wafer must be diced with the MEMS devices unprotected, thereby increasing the risk of damage to the devices. It is also difficult to achieve and maintain a hermetic seal because of the variety of materials used.

Yet another approach is to form a number of MEMS devices on a first wafer and an equal number of cavities in a second wafer and to use wafer-bonding technology to join the wafers together such that the MEMS devices are each disposed within a cavity in the opposed wafer. This approach requires precise alignment of the wafers when bonding and complicates subsequent dicing operations. This approach also leads to a significant increase in the overall size of each MEMS device because of the need to use a relatively thick wafer for creation of the cavities.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a cross-sectional elevation of an embodiment of an encapsulated micro-electro-mechanical (MEMS) device.

FIG. 2A is a cross-sectional elevation of an initial part of an embodiment of a process for encapsulating a MEMS device, such as the encapsulated MEMS device shown in FIG. 1.

FIG. 2B is a cross-sectional elevation of a subsequent part of an embodiment of a process for encapsulating a MEMS device, such as the encapsulated MEMS device shown in FIG. 1.

FIG. 2C is a cross-sectional elevation of a subsequent part of an embodiment of a process for encapsulating a MEMS device, such as the encapsulated MEMS device shown in FIG. 1.

FIG. 2D is a cross-sectional elevation of a subsequent part of an embodiment of a process for encapsulating a MEMS device, such as the encapsulated MEMS device shown in FIG. 1.

FIG. 2E is a cross-sectional elevation of a subsequent part of an embodiment of a process for encapsulating a MEMS device, such as the encapsulated MEMS device shown in FIG. 1.

FIG. 2F is a cross-sectional elevation of a subsequent part of an embodiment of a process for encapsulating a MEMS device, such as the encapsulated MEMS device shown in FIG. 1.

FIG. 2G is a cross-sectional elevation of a subsequent part of an embodiment of a process for encapsulating a MEMS device, such as the encapsulated MEMS device shown in FIG. 1.

### DETAILED DESCRIPTION OF THE ILLUSTRATED EMBODIMENTS

Embodiments of an apparatus and process for micro-electro-mechanical (MEMS) device encapsulation using buried porous silicon are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

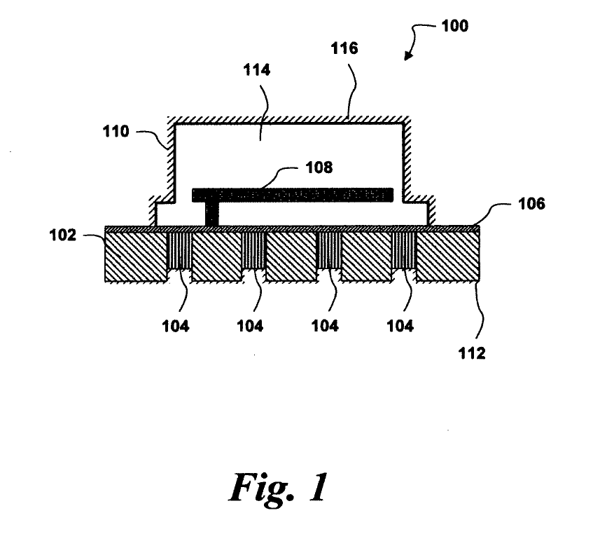

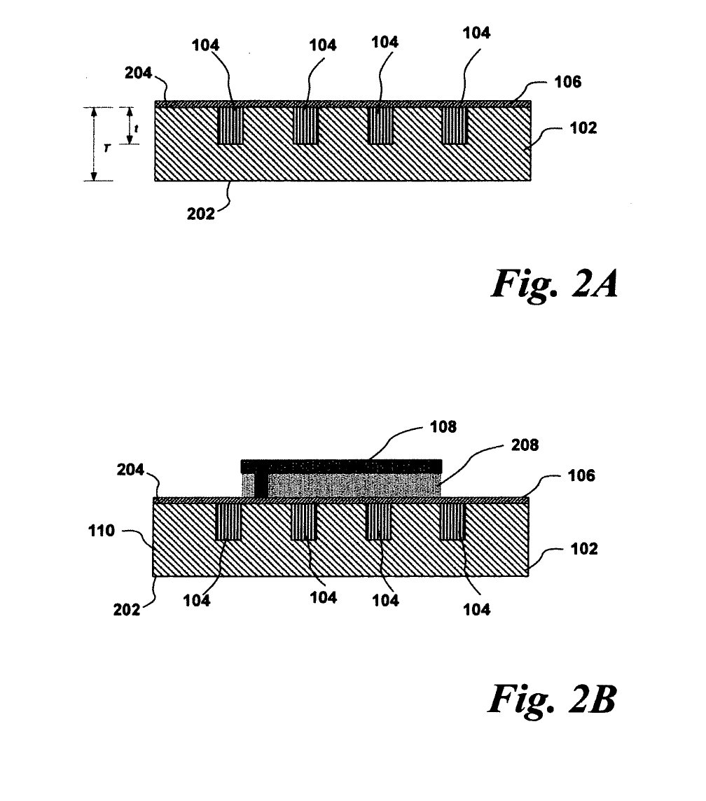

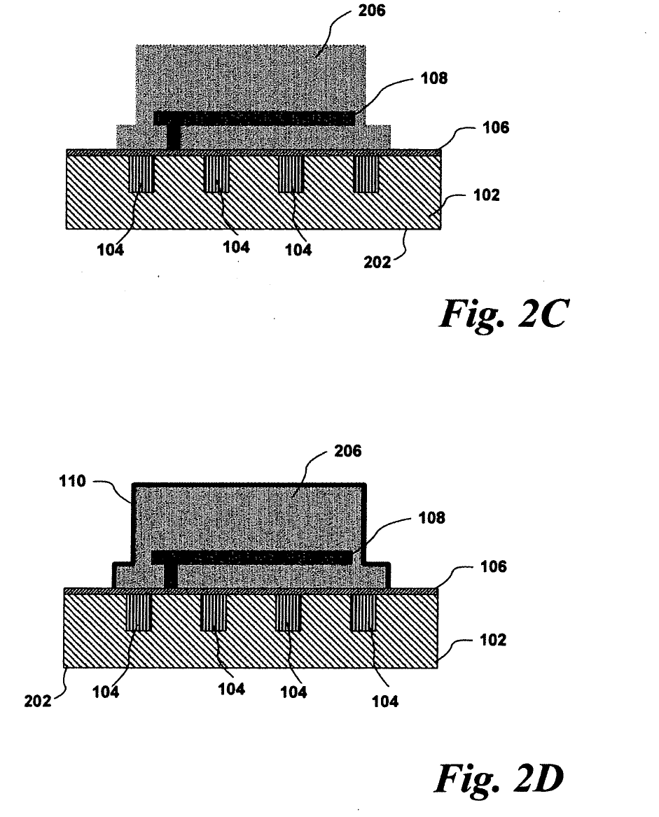

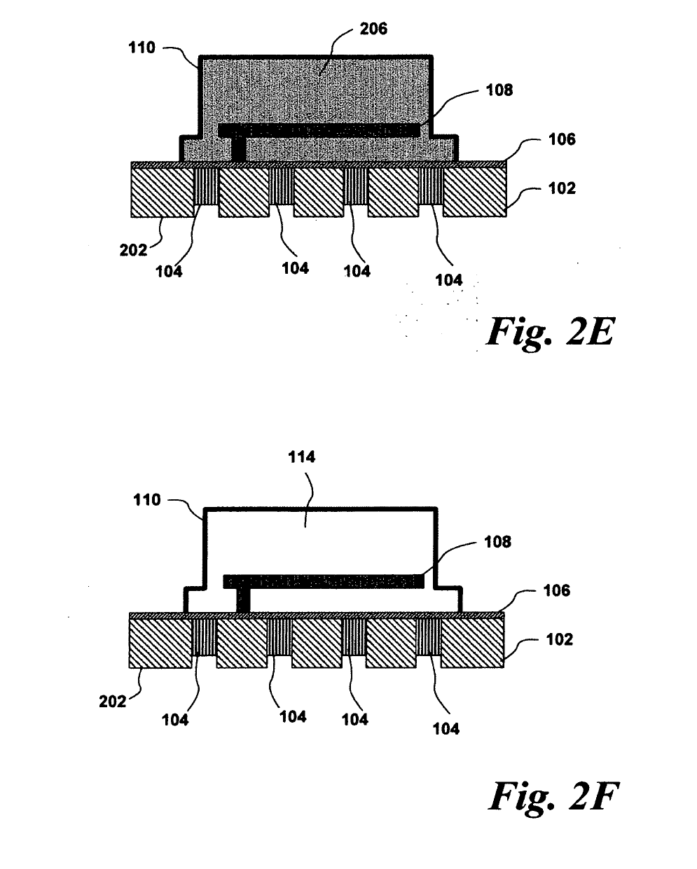

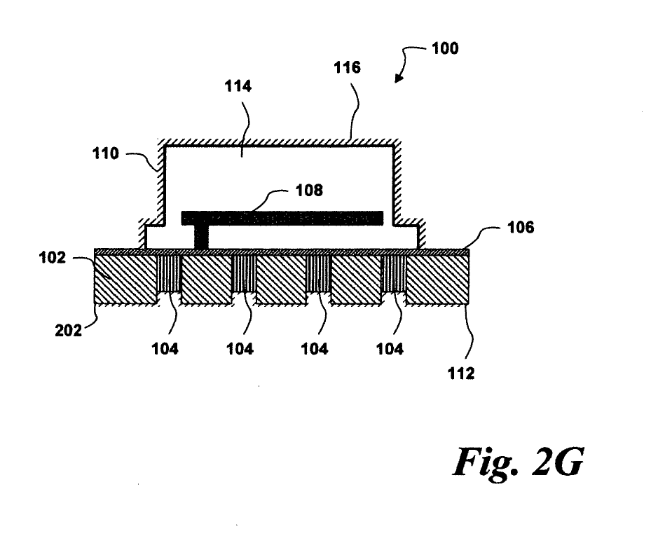

FIG. 1 illustrates an embodiment of an encapsulated micro-electro-mechanical (MEMS) device 100. Encapsulated MEMS device 100 includes a substrate 102 in which are formed several porous regions 104. A MEMS device 108 is formed on a front or top side of substrate 102, and can be hermetically encapsulated in a sealed volume 114 by cap 110 and sealing layer 116. A further sealing layer 112 is applied to a back side or bottom of substrate 102 to seal the exposed backsides of porous regions 104, thus preventing entry of undesired contaminants into sealed volume 114 through porous areas 104. Further details of the encapsulated MEMS device 100 are described below with reference to FIGS. 2A-2G, which describe an embodiment of a process used to make the encapsulated MEMS device 100.

FIGS. 2A-2G together illustrate an embodiment of a process for encapsulating a MEMS device such as encapsulated MEMS device 100 shown in FIG. 1. FIG. 2A illustrates an initial part of the process, in which at least one porous region 104 is formed in substrate 102. Substrate 102 can be any kind of substrate that is compatible with the manufacturing requirements for MEMS device 108 (see FIG. 1) and whose properties are consistent with the construction of the MEMS device and formation of the porous regions 104. In one embodiment, for example, substrate 102 can be one or more of the various forms of silicon, such as polysilicon, single-crystal silicon, and the like. In other embodiments, substrate 102 can be made of different materials.

Porous regions 104 can be formed in substrate 102 in a variety of ways. In the embodiment shown, substrate 102 has a thickness T corresponding to the distance between front side 204 of the substrate and back side 202 of the substrate. Porous regions 104 extend from front side 204 of the substrate to some position between front side 204 and back side 202 and have a thickness t that, in the embodiment shown, is less than the thickness T of the substrate. Thus, in the embodiment shown the ratio t/T is less than one, but in other embodiments the ratio can take on any value between and including zero and one; this means that porous regions 104 can be very shallow and substantially at the front surface 204 of substrate 102, or can be very deep and extend through substantially the entire thickness T of substrate 102. The illustrated embodiment has four regularly-spaced porous regions 104, all with the same shape and size, but in other embodiments there can be more or less regions, the regions can have different shapes and sizes, and they can be spaced irregularly. Moreover, in an embodiment with multiple porous regions 104 all the porous regions need not have the same shape or size.

In one embodiment, porous regions 104 can be formed in substrate 102 by first patterning and etching substrate 102 to form features such as trenches or holes; the exact shapes and sizes of the features will depend on the shapes and sizes desired for porous regions 104. After the features are formed in substrate 102, a filling material is deposited on front side 204 to fill the features. The process used to deposit the filling material will depend on the exact porous material used; in various embodiments, the filling material can be deposited using physical vapor deposition (PVD), chemical vapor deposition (CVD), atomic layer deposition (ALD), sputtering, or any of various other deposition processes known in the art. If necessary, after deposition of the filling material front side 204 of substrate 102 can be planarized to remove filling material from the field surrounding the features.

Any of various porous materials can be used in porous regions 104. In one embodiment, the porous material used in porous regions 104 is a porous silicon, or oxidized porous silicon (nominally SiO₂) that has been processed to increase its porosity. For example, the porosity of oxidized porous silicon (silicon oxide) can be altered (i.e., it can be made more or less porous) by increasing or decreasing the amount of air in the mix. In other embodiments, of course, other porous materials such as appropriate resins or other organic and inorganic materials can be used.

After porous regions 104 are complete, a passivation layer 106 is formed on front side 204 of substrate 102. Formation of passivation layer 106 is a process in which chemically and electrically active broken bonds at the front side 204 are saturated, and hence de-activated, by reaction with selected elements. For example, hydrogen passivates broken silicon (Si) bonds at the surface; oxides grown on a silicon surface passivate it as well. Essentially, then, passivation prevents bonds between the semiconductor surface and other elements.

FIG. 2B illustrates the next part of the process embodiment for encapsulating a MEMS device. After formation of passivation layer 106 on front side 204 of substrate 102 as shown in FIG. 2A, MEMS device 108 is formed on the substrate. Although shown in the illustrated embodiment as a device including a cantilever beam, in other embodiments MEMS device 108 can be any kind of MEMS device. MEMS device 108 is formed on substrate 102 using techniques well-known in the art for building MEMS devices. MEMS fabrication requires the release of compliant mechanical structures. A sacrificial layer is typically used to provide as a structural layer on which device layers can be deposited and subsequently removed to leave a suspended or freestanding device. In the embodiment shown, most of the sacrificial layers used during construction have been removed from MEMS device 108, although a portion 208 of a sacrificial layer that lies between MEMS device 108 and front side 204 of the substrate can be left in place.

FIG. 2C illustrates the next part of the process embodiment for encapsulating a MEMS device. After MEMS device 108 is formed on substrate 102 as shown in FIG. 2B, a sacrificial layer 206 is deposited on substrate 102. After deposit, sacrificial layer 206 is patterned and etched so that it substantially encases both MEMS device 108 and the sacrificial layer portion 208 left over from construction of MEMS device 108; both sacrificial layer 206 and left-over sacrificial layer portion 208 are hereafter referred to as sacrificial layer 206. Sacrificial layer 206 is positioned such that it is over at least one of the porous regions 104. In one embodiment, sacrificial layer 206 is made of silicon oxide (nominally SiO₂), but in other embodiments the sacrificial layer can be made of other materials such as polysilicon, polyimide, photoresists or other sacrificial materials not listed here.

FIG. 2D illustrates the next part of the process embodiment for encapsulating a MEMS device. After formation of sacrificial layer 206 over and around MEMS device 108 as shown in FIG. 2C, a cap layer is deposited on substrate 102 and sacrificial layer 206. After deposit, the cap layer is patterned and etched to form a cap 110 that substantially conforms to the contours of sacrificial layer 206, and substantially encapsulates MEMS device 108 and sacrificial layer 206. Like sacrificial layer 206, cap 110 is positioned on substrate 102 such that it lies over at least one of the porous regions 104. In one embodiment, cap 110 can hermetically seal everything within, but in other embodiments cap 110 need not form a hermetic enclosure. In one embodiment, cap 110 is formed of gold, although in other embodiments cap 110 can be formed of other materials such as polysilicon, silicon nitride or other materials.

FIG. 2E illustrates the next part of the process embodiment for encapsulating a MEMS device. After formation of cap 110 over and around MEMS device 108 and sacrificial layer 206 as shown in FIG. 2D, back side 202 of substrate 202 is selectively etched or/and physically removed (i.e. by grinding) to expose at least one of the porous regions 104. The amount of back side etching or removal necessary to expose the porous regions 104 within substrate 102 will depend in part on how deeply porous regions 104 are formed or buried in substrate 102—in other words, the necessary amount of back side etching or removal will depend on the ratio t/T (see FIG. 2A and associated text).

FIG. 2F illustrates the next part of the process embodiment for encapsulating a MEMS device. After etching the back side of substrate 102 to expose at least one of the porous areas 104 as shown in FIG. 2E, the exposed porous regions on the back side of substrate 102 provide a way by which etchant can be introduced in to the volume encapsulated by cap 110 to remove the sacrificial layer 206 within the cap. Thus, etchant is introduced into the interior of cap 110 for a time necessary to etch away the sacrificial layer 206. When the etchant is in the interior of cap 110, it dissolves the sacrificial layer 206, thus releasing MEMS device 108 contained within cap 110. Just as the etchant flowed into the interior of cap 110 through porous regions 104, as sacrificial layer 206 dissolved the etchant flows out of the interior of cap 110 through porous regions 104, taking with it the dissolved sacrificial layer and leaving behind a released MEMS device in a volume 114 inside the cap.

FIG. 2G illustrates the final part of the process embodiment for encapsulating a MEMS device. After using porous portions 104 to etch sacrificial layer 206 from the interior of cap 110, as shown in FIG. 2F, a sealing layer 112 is formed on the back side 202 of substrate 102. Back side sealing layer 112 seals and protects the back sides of porous regions 104 and prevents entry of undesired contaminants or gases into volume 114 through any of porous regions 104. Similarly, a sealing layer 116 can also be applied to cap 110 and to the front side of substrate 102. Sealing layer 116 seals cap 110 and prevents entry of undesired gases or contaminants into volume 114 through cap 110. As a result of applying sealing layers 112 and 116, volume 114 is hermetically sealed. As noted above, though, the construction and arrangement of cap 110 and sealing layers 112 and 116 can be such that volume 114 is not hermetically sealed.

Both front side sealing layer 116 and back side sealing layer 112 can be formed using known deposition techniques, although the exact conditions may vary depending on the conditions required within volume 114. For example, in an embodiment where volume 114 is to be hermetically sealed and a vacuum, low pressure, or inert gas fill is required inside volume 114, deposition of the sealing layers can take place in the appropriate atmospheric conditions. In other embodiments where volume 114 is not hermetically sealed, the sealing layers can be applied under different conditions or omitted completely.

In the embodiment shown both front side sealing layer 116 and back side sealing layer 112 are made of the same material, but in other embodiments the sealing layers 112 and 116 need not be made of the same material. In still other embodiments, front side sealing layer 116 and/or back side sealing layer 112 need not be applied at all, depending on the materials used for cap 110 and on other requirements, such as whether volume 114 is required to be hermetically sealed. In one embodiment, sealing layers 112 and 116 can be made using silicon nitride, but in other embodiments different materials such as silicon oxide, BPSG, PSG, germanium, aluminum, polyamide or other materials.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An apparatus comprising:
a substrate having therein one or more porous regions;
a micro-electro-mechanical (MEMS) device formed on the substrate;
a cap formed on the substrate, wherein the cap encapsulates the MEMS device and is formed over at least one of the one or more porous regions; and
a sealing layer formed on a back side of the substrate.

2. The apparatus of claim 1 wherein the porous regions extend from a front side of the substrate to a position between the front side and the back side.

3. The apparatus of claim 1 wherein the plurality of porous regions are made using porous silicon.

4. The apparatus of claim 1 wherein the MEMS device is formed proximate to one of the one or more porous regions.

5. The apparatus of claim 1, further comprising a passivation layer on a front side of the substrate.

6. The apparatus of claim 1, further comprising a sealing layer formed on a front side of the substrate and on the cap.

7. A process comprising:
forming one or more porous regions in a substrate;
forming a micro-electro-mechanical (MEMS) device on the substrate;
forming a sacrificial layer on the substrate over the MEMS device, wherein the sacrificial layer is over at least one of the one or more porous regions;
forming a cap on the substrate, wherein the cap encapsulates the MEMS device and the sacrificial layer;
etching the sacrificial layer inside the cap by inserting etchant through at least one of the one or more porous regions; and
forming a sealing layer on a back side of the substrate.

8. The process of claim 7 wherein the porous regions extend from a front side of the substrate to a position between the front side and the back side.

9. The process of claim 8, wherein etching the sacrificial layer inside the cap comprises:
etching the backside of the substrate to expose a backside of at least one of the plurality of porous regions; and
inserting etchant into an interior of the cap through the at least one porous region whose backside is exposed.

10. The process of claim 7, further comprising forming a passivation layer on the front side of the substrate.

11. The process of claim 7, further comprising forming a sealing layer on a front side of the substrate and on the cap.

12. An apparatus made by a process comprising:
forming one or more porous regions in a substrate;
forming a micro-electro-mechanical (MEMS) device on the substrate;
forming a sacrificial layer on the substrate over the MEMS device, wherein the sacrificial layer is over at least one of the one or more porous regions;
forming a cap on the substrate, wherein the cap encapsulates the MEMS device and the sacrificial layer;
etching the sacrificial layer inside the cap by inserting etchant through at least one of the one or more porous regions; and
forming a sealing layer on a back side of the substrate.

13. The apparatus of claim 12 wherein the porous regions extend from a front side of the substrate to a position between the front side and the back side.

14. The apparatus of claim 13, wherein etching the sacrificial layer inside the cap comprises:
etching the backside of the substrate to expose a backside of at least one of the plurality of porous regions; and
inserting etchant into an interior of the cap through the at least one porous region whose backside is exposed.

15. The apparatus of claim 12, wherein the process further comprises forming a passivation layer on the front side of the substrate.

16. The apparatus of claim 12, wherein the process further comprises forming a sealing layer on a front side of the substrate and on the cap.
